(19) United States
(12) Patent Application Publication
(10) Pub. No.: US 2026/0354118 A1
(43) Pub. Date: Nov. 5, 2026

(54) Methods and Apparatus for Estimation of Post-Bonding Sub-Pixel Misalignment of Component and Substrate

(71) Applicant: Applied Materials, Inc., Santa Clara, CA (US)

(72) Inventors: Srinivas CHUKKA, San Jose, CA (US); Yau Loong CHONG, Singapore (SG); Gokul GANESAN, Bangalore (IN); Albin GEORGE, Bengaluru (IN); Ankit KAPOOR, San Jose, CA (US)

(21) Appl. No.: 19/194,491

(22) Filed: Apr. 30, 2025

(51) Int. Cl. H10P 74/20; G01N 21/88; G03F 7/00; H10P 74/00; H10W 46/00

(52) U.S. Cl. CPC H10P 74/203; G01N 21/8851; H10P 74/235; H10P 74/277; H10W 46/00; G03F 7/706839

(57) ABSTRACT

Methods and systems for processing a substrate include, for a component that is bonded to a substrate, separately detecting a substrate and component fiducial using a captured image of the component bonded to the substrate, wherein separately detecting the substrate and component fiducial each includes processing the captured image using a histogram of gradients and computing a two-dimensional matched filter image response to a geometric shape template to obtain a coarse fit representation of the substrate and component fiducial at pixel-level localization accuracy, and sub-pixel fitting the two-dimensional matched filter image response to the geometric shape template to obtain a fine fit representation of the substrate and component fiducial; determining, from the detected substrate and component fiducial, a center of the substrate and component fiducial; calculating a difference between the center of the substrate and component fiducial; and reporting the difference to a bonding system as feedback.

### FIELD

Embodiments of the present disclosure generally relate to methods and systems for inspecting bonding, and more specifically, to methods and systems for estimation of post-bonding misalignment of component and substrate fiducials.

### BACKGROUND

Bonding (e.g., fusion bonding, hybrid bonding) is a semiconductor fabrication process where a component (e.g., a die) and a substrate are aligned and bonded together. Due to stringent alignment tolerances for bonding the component and the substrate, the metrology specification for estimating the misalignment between a component and substrate requires sub-pixel optical measurement accuracy and precision (i.e., to nanometer scale). One specification, for example, may require a measurement accuracy that is less than 1/50 sub pixel and a measurement precision (1 sigma: 3 nm) that less than 1/150 pixel. Existing image analysis methods used in semiconductor metrology systems are not capable of estimating the misalignment to the required precision and accuracy.

Thus, the inventors provide methods and systems for estimation of post-bonding sub-pixel misalignment of components and substrates.

### SUMMARY

Methods and systems for estimation of post-bonding sub-pixel misalignment of components and substrates are provided herein. In some embodiments, a method for processing a substrate includes: for a component that is bonded to a substrate, separately detecting a substrate fiducial and a component fiducial using a captured image of the component bonded to the substrate, wherein separately detecting the substrate fiducial and the component fiducial each includes processing the captured image using a histogram of gradients and computing a two-dimensional matched filter image response to a geometric shape template to obtain a coarse fit representation of the substrate fiducial and the component fiducial at pixel-level localization accuracy, and sub-pixel fitting the two-dimensional matched filter image response to the geometric shape template to obtain a fine fit representation of the substrate fiducial and the component fiducial; determining to sub-pixel precision, from the detected substrate fiducial and component fiducial, a center of the substrate fiducial and a center of the component fiducial; calculating a two-dimensional positional difference between the center of the substrate fiducial and the center of the component fiducial; and reporting the two-dimensional positional difference to a bonding system as feedback for a bonding process of a subsequent component and subsequent substrate.

In some embodiments, a non-transitory computer readable storage medium storing instructions, which when executed by a processor, perform a method for processing a substrate. The method includes: for a component that is bonded to a substrate, separately detecting a substrate fiducial and a component fiducial using a captured image of the component bonded to the substrate, wherein separately detecting the substrate fiducial and the component fiducial each includes processing the captured image using a histogram of gradients and computing a two-dimensional matched filter image response to a geometric shape template to obtain a coarse fit representation of the substrate fiducial and the component fiducial at pixel-level localization accuracy, and sub-pixel fitting the two-dimensional matched filter image response to the geometric shape template to obtain a fine fit representation of the substrate fiducial and the component fiducial; determining to sub-pixel precision, from the detected substrate fiducial and component fiducial, a center of the substrate fiducial and a center of the component fiducial; calculating a two-dimensional positional difference between the center of the substrate fiducial and the center of the component fiducial; and reporting the two-dimensional positional difference to a bonding system as feedback for a bonding process of a subsequent component and subsequent substrate.

In some embodiments, a system includes: an image acquisition device configured to capture an infrared (e.g., short-wavelength infrared, SWIR) image of a component fiducial on a component and substrate fiducial on a substrate that is bonded to the component; and a controller configured to: separately detect the substrate fiducial and the component fiducial using the captured infrared image, wherein separately detecting the substrate fiducial and the component fiducial each includes processing the infrared image using a histogram of gradients and computing a two-dimensional matched filter image response to a geometric shape template to obtain a coarse fit representation of the substrate fiducial and the component fiducial at pixel-level localization accuracy, and sub-pixel fitting the two-dimensional matched filter image response to the geometric shape template to obtain a fine fit representation of the substrate fiducial and the component fiducial; determine to sub-pixel precision, from the detected substrate fiducial and component fiducial, a center of the substrate fiducial and a center of the component fiducial; calculate a two-dimensional positional difference between the center of the substrate fiducial and the center of the component fiducial; and report the two-dimensional positional difference to a bonding system as feedback for a bonding process of a subsequent component and subsequent substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 shows a schematic of a system in accordance with some embodiments of the present disclosure.

FIG. 2 shows a schematic of a metrology system in accordance with some embodiments of the present disclosure.

FIG. 3 shows an image of a component and a substrate including fiducials captured by the metrology system of FIG. 2 in accordance with some embodiments of the present disclosure.

FIG. 4 shows estimated locations of centers of component fiducial and substrate fiducials in accordance with some embodiments of the present disclosure.

FIG. 5 shows a method in accordance with some embodiments of the present disclosure.

FIG. 6 shows examples of coarse and fine fitting of component and substrate fiducials in accordance with the method shown in FIG. 5.

FIG. 7 shows a controller and a user device in accordance with some embodiments of the present disclosure.

FIG. 8 shows a method in accordance with some embodiments of the present disclosure.

FIG. 9 shows a method in accordance with some embodiments of the present disclosure.

FIG. 10 shows a method in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and systems for estimation of post-bonding sub-pixel misalignment of components and substrates are provided herein. The methods and systems described herein are applicable to any bonding process (e.g., fusion bonding, die-to-wafer (D2W) hybrid bonding, chip-to-wafer (C2W) hybrid bonding) where it may be useful to estimate the misalignment between substrate fiducials and component fiducials.

Embodiments of the methods and systems described herein are useful to inspect and estimate component (e.g., die) level misalignment in capture image(s) of components (e.g., dies) and substrates which have a combination of substrate fiducials and component fiducials. The methods and systems described herein use images (e.g., infrared images) of a component and substrate that have been bonded together in a bonding process. The methods and systems estimate the misalignment between the center of a substrate fiducial and the center of a component fiducial with sub-pixel accuracy and precision, which is not possible with existing methods and systems.

The methods and systems in accordance with the present disclosure improve the field of metrology for inspection of substrates and components that have been bonded by a bonding process. The measurements may be fed back to the bonding process that bonded the component to the substrate to adjust process parameters of the bonding process for bonding a subsequent component and substrate. As a result of the improved accuracy and precision in the measurement of misalignment between component and substrate, process control of the bonding process may also be improved.

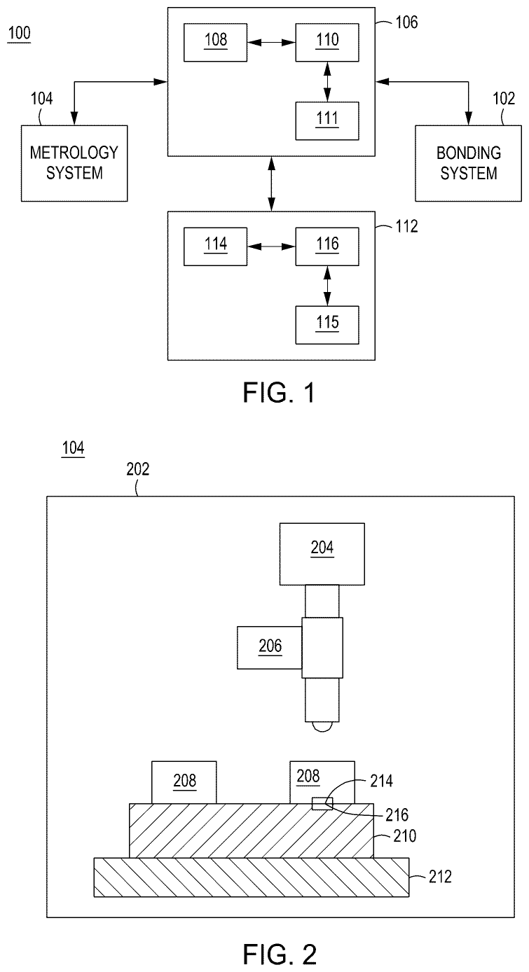

FIG. 1 shows a schematic of a system 100 in accordance with some embodiments of the present disclosure. The system 100 includes a bonding system 102 (e.g., fusion or hybrid bonding system) in which a component (e.g., a die) is bonded to a substrate. The bonding system 102 may be any commercially available bonding system, such as those available from Applied Materials of Santa Clara, California. The system 100 also includes a metrology system 104 that is configured to receive the component and substrate after the bonding process is completed and perform an inspection process to measure the misalignment between the component and the substrate, as described in greater detail herein. The system 100 also includes a controller 106 and a user device 112 coupled to the bonding system 102 and the metrology system 104 to control the operation of the bonding system 102 and the metrology system 104. The controller 106 may include a processor 108 (e.g., a central processing unit, CPU) and a non-transitory computer readable storage medium 110 storing instructions, which when executed by the processor 108, perform a method for processing a substrate described in greater detail herein. The non-transitory computer readable storage medium 110 may be one or more of readily available memory such as random access memory (RAM), read only memory (ROM), floppy disk, hard disk, optical storage media (e.g., compact disc or digital video disc), flash drive, or any other form of digital storage, local or remote. The controller 106 may also include support circuits 111. The support circuits 111 are coupled to the processor 108 for supporting the processor 108 in a conventional manner. The support circuits 111 may include cache, power supplies, clock circuits, input/output circuitry and subsystems (e.g., keyboard, mouse, display screen), and the like. Inventive methods as described herein may be stored in the non-transitory computer readable storage medium 110 as software routine that may be executed or invoked to control the operation of the bonding system 102 and the metrology system 104 in the manner described herein. The software routine may also be stored and/or executed by a second processor (not shown) that is remotely located from the hardware being controlled by the processor 108.

In some embodiments, and as shown in FIG. 1, the system 100 may also include a user device 112, which may include a processor 114 (e.g., a CPU) and non-transitory computer readable storage medium 116 storing instructions, which when executed by the processor 114 perform a method for configuring parameters used by the controller 106, as described in greater detail below. The non-transitory computer readable storage medium 116 may be one or more of readily available memory such as random access memory (RAM), read only memory (ROM), floppy disk, hard disk, optical storage media (e.g., compact disc or digital video disc), flash drive, or any other form of digital storage, local or remote. The user device 112 may also include support circuits 115. The support circuits 115 are coupled to the processor 114 for supporting the processor 114 in a conventional manner. The support circuits 115 may include cache, power supplies, clock circuits, input/output circuitry and subsystems (e.g., keyboard, mouse, display screen), and the like. Inventive methods as described herein may be stored in the non-transitory computer readable storage medium 116 as software routine that may be executed or invoked to control the operation of the bonding system 102 and the metrology system 104 in the manner described herein. The software routine may also be stored and/or executed by a second processor (not shown) that is remotely located from the hardware being controlled by the processor 114.

FIG. 2 shows a schematic of the metrology system 104 in accordance with some embodiments of the present disclosure. The metrology system 104 may include a chamber 202 housing an image acquisition device (e.g., a camera) 204 and a light source 206 which are configured for capturing an image of a component 208 and a substrate 210 bonded together by a bonding process (e.g., fusion bonding process, hybrid bonding process). The component 208 may be a die. The camera 204 may be an indium gallium arsenide (InGaAs) camera configured to capture infrared (e.g., SWIR) images. The metrology system 104 may include a stage 212 that supports the component 208 and the substrate 210 in the chamber 202. In some embodiments, the stage and/or the camera may be movable horizontally and/or vertically to facilitate imaging of one or more sites of the component 208 and/or substrate 210.

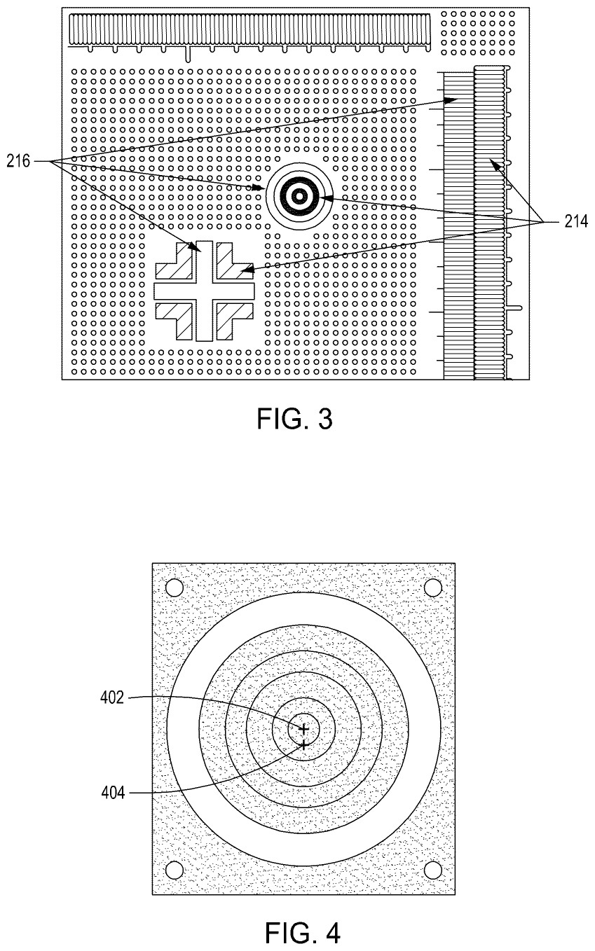

The component 208 and the substrate 210 may include fiducials used for alignment. The fiducials may have geometric shapes, such as circular or polygonal, and any combination of geometric shapes. Polygons can be any known polygon or a generic polygon, such as triangular, rectangular, octagon, and hexagon. In FIG. 2, the component 208 is bonded to the top of the substrate 210 and the substrate 210 is supported on a bottom surface of the substrate 210 by the stage 212. In some embodiments, and as shown in FIG. 2, a component fiducial 214 and a substrate fiducial 216 may be located at the same Z plane, e.g., at the interface between the component 208 and the substrate 210, such that a single-focus image may be captured that includes both the substrate fiducial and the component fiducial. In some embodiments, the component and substrate fiducials may be located in different Z planes, such that a multi-focus image may be captured for the substrate fiducial and the component fiducial. In embodiments, and as shown in FIG. 3, the captured image may include features of the component (e.g., component fiducials 214) and features of the substrate (e.g., substrate fiducials 216). During an inspection process, a plurality of inspection sites (e.g., four corners) of the component 208 may be imaged as described herein.

FIG. 4 shows an example of the position (x_comp, y_comp) of the center 402 of the component fiducial 214 and the position (x_sub, y_sub) of the center 404 of the substrate fiducial 216. In FIG. 4, the center 402 and center 404 are misaligned by a non-zero difference Delta_xy=[x_comp-x_sub, y_comp-y_sub], which may be measured and used for providing feedback to the bonding process as described in greater detail herein.

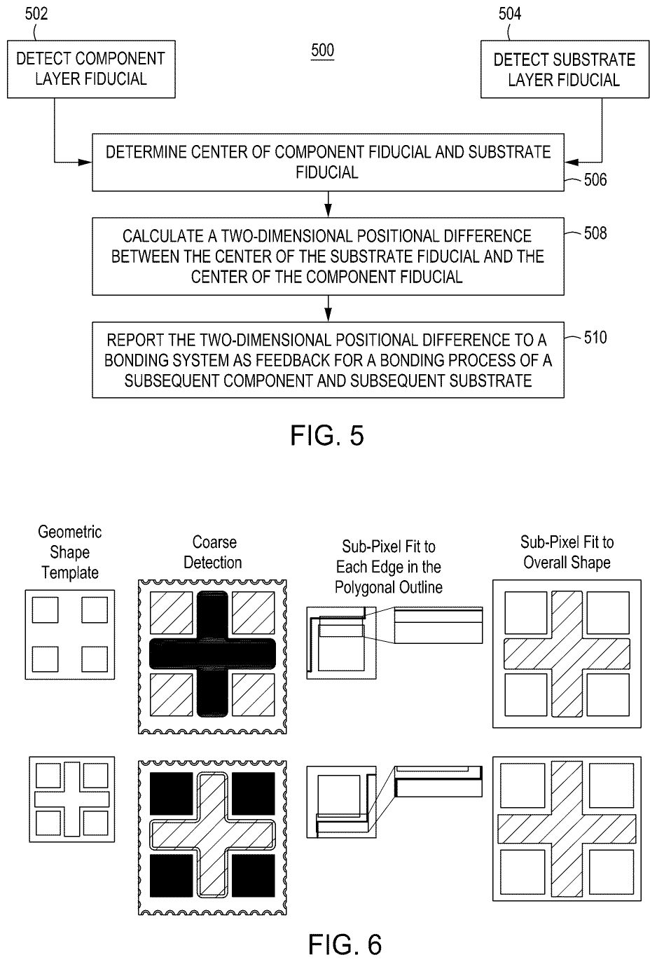

FIG. 5 shows a method 500 for processing a substrate according to some embodiments of the present disclosure. At blocks 502 and 504, for a component that is bonded to a substrate, the method 500 includes separately detecting a substrate fiducial and a component fiducial using a captured image of the component bonded to the substrate. In some embodiments, the captured image is at least one of a single-focused infrared (e.g., SWIR) image for substrate and component fiducials in the same Z plane, or a dual-focused infrared (e.g., SWIR) image for substrate and component fiducial in different Z planes.

In embodiments, separately detecting the substrate fiducial and the component fiducial each includes processing the captured image using a histogram of gradients and computing a two-dimensional matched filter image response to a geometric shape template to obtain a coarse fit representation of the substrate fiducial and the component fiducial at pixel-level localization accuracy. In embodiments, processing of the captured image may only reasonably be performed electronically with the aid of a device (e.g., the controller 106) due to computational complexity, speed, and/or volume. In some embodiments, the processing of the captured image may be performed by the controller 106. The geometric shape template may include one or more circular or polygonal shapes or combinations thereof. FIG. 6 shows a coarse fit representation of the component fiducial (upper row) and the substrate fiducial (lower row). Separately detecting the substrate fiducial and the component fiducial may also each include sub-pixel fitting the two-dimensional matched filter image response to the geometric shape template to obtain a fine fit representation of the substrate fiducial and the component fiducial. In some embodiments, sub-pixel fitting includes fitting the matched filter image response to the geometric shape template around a sub-pixel spatial region of the matched filter image response. FIG. 6 shows a fine fit representation of component fiducial (upper row) and the substrate fiducial (lower row).

At block 506, the method 500 may include determining or otherwise identifying to sub-pixel precision, from the detected substrate fiducial and component fiducial, a center of the substrate fiducial and a center of the component fiducial. At block 508, the method 500 may include calculating a two-dimensional positional difference between the center of the substrate fiducial and the center of the component fiducial.

At block 510, the method 500 may include reporting the two-dimensional positional difference to a bonding system 102 (e.g., bonding system for die-to-wafer (D2W), chip-to-wafer (C2W)) as feedback for a bonding process of a subsequent component and subsequent substrate. In some embodiments, the method 500 may include modifying parameters of the bonding process performed in the bonding system based on the reported difference, and bonding a second component to a second substrate using the bonding process.

In some embodiments, the method 500 may include generating the geometric shape template based on at least one of expected shape, size, spatial arrangement, and relative intensity polarity with respect to the background of the substrate fiducial and the component fiducial or shape of the substrate fiducial and the component fiducial.

In some embodiments, if all fiducials have not yet been detected, the method 500 may include repeating blocks 502-512 for a second (or additional) substrate fiducial and a second (or additional) component fiducial. The method 500 may include calculating an affine transformation of the component using the center of the substrate fiducial and the center of the component fiducial, and the center of the second (or additional) substrate fiducial and a center of the second (or additional) component fiducial. The affine transformation may be used to identify rotational misalignment between the substrate and the component. The method 500 may include reporting the affine transformation to the bonding system 102 as feedback for the bonding process. In some embodiments, the method 500 may include modifying parameters of the bonding process based on the affine transformation, and bonding a second component to a second substrate using the bonding process. In some embodiments, the method 500 may further include calculating a difference between the center of the second (or additional) substrate fiducial and the center of the second (or additional) component fiducial and reporting the difference to the bonding system 102 as feedback for the bonding process.

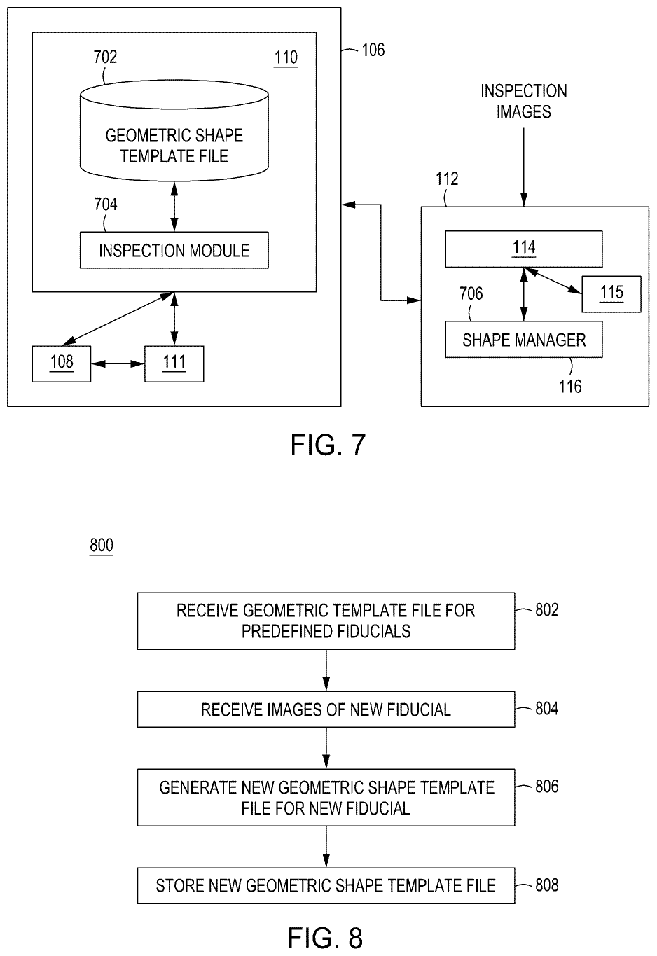

FIG. 7 shows the controller 106 and the user device 112 in accordance with some embodiments of the present disclosure. In some embodiments, and as shown in FIG. 7, the non-transitory computer readable storage medium 110 may include geometric shape template files 702 (e.g., JSON files) for substrate fiducials and component fiducials. Also, the non-transitory computer readable storage medium 110 may include an inspection module 704 configured for processing the geometric shape template files 702 and carrying out the methods described herein for processing substrates using the geometric shape template files, such as the method 500. The non-transitory computer readable storage medium 116 of the user device 112 may store a shape manager 706 that may be executed by the processor 114 to define the geometric shape template files 702. The shape manager 706 may be used to define geometric shape template files when a new fiducial needs to be created.

In some embodiments, the shape manager 706, may be an off-line application, which may be run independently of the inspection module 704. The shape manager 706 may also be used for debugging and overlay, repeatability, and reproducibility (ORR) computation, as discussed in greater detail herein. The inputs to the shape manager 706 may include stored geometric shape template files 702 for predefined fiducials, and images (e.g., infrared images) of the new fiducials, which may be captured using the metrology system 104 described herein and imported into the shape manager 706. The output of the shape manager 706 is a new geometric shape template file that may be used by the inspection module 704. The output geometric shape template file will have all the required information to inspect the new fiducials using the controller according to the methods described herein, such as the method 500. In some embodiments, the geometric shape template file may be a JSON file that contains all information about 1) shape parameters 2) inspection algorithm parameters for coarse and fine fit-both for substrate fiducials and component fiducials.

FIG. 8 shows a method 800 for creating new geometric shape template files in accordance with some embodiments of the present disclosure. The method 800 may be performed at least in part by the shape manager 706. At block 802, the method 800 includes receiving geometric shape template files 702 for predefined fiducials. The predefined fiducials may have basic geometric shapes (e.g., circles, polygons, such as squares, triangles, hexagons, octagons), which may be used as building blocks to generate new fiducial shapes. At block 804, the method 800 may include receiving an image (e.g., infrared image) of a new fiducial captured from a component bonded to a substrate. The image may be received from the metrology system 104 described above. In some embodiments, the method 800 may include moving the stage 212 (e.g. manually or automatically) to a known fiducial mark location, focusing the image on the fiducial, and capturing an image of the fiducial. The method 800 may also include transferring (e.g., manually or automatically) the captured image to the shape manager 706. The image may be encrypted, e.g., to prevent or otherwise limit using the image with other applications. At block 806, the method 800 may include generating a new geometric shape template file for the new fiducial based on the received geometric shape template file 702 and the received images of the new fiducial. At block 808, the method 800 may include storing the new geometric shape template file for use by the inspection module 704.

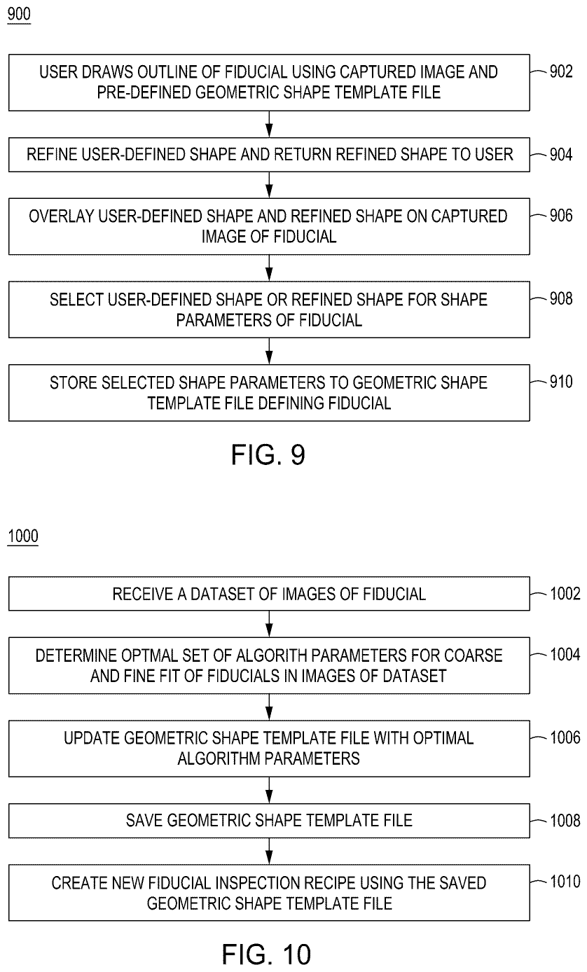

FIGS. 9 and 10 show additional details of block 806 in accordance with some embodiments of the present disclosure. FIG. 9 shows a method for creating shape parameters for the geometric shape template file for component and substrate fiducials. FIG. 10 shows a method 1000 for completing the geometric shape template file with parameters used by the controller 106 for carrying out the coarse fitting and fine fitting of the method 500. The method 900 may include importing the captured image into the shape finder system and creating a new fiducial definition workspace in a user interface (e.g., a graphical user interface), which may be displayed on a display screen of the user device 112.

At block 902, within the user interface, a user may view the captured image and draw (e.g., using an input device (e.g., keyboard and/or mouse) of the user device 112) an outline of the fiducial using the captured image and the existing geometric shape template files for predefined fiducials. In some embodiments, a user may interactively outline or draw the new shape for the component and substrate fiducials, based on their appearance in the image (e.g., infrared image) received by the shape manager 706. The user interface may have a capability to allow a user to import and receive the image and draw shapes on top of the image. In some embodiments, a user may be able to create predefined shapes (e.g., circle, rectangle, hexagon, etc.), such as by using a drop-down control or other menu to select existing fiducial shapes and patterns from the preexisting fiducial shapes. Also, a user may be able to create a custom polygon using connected linear segments. In some embodiments, the user may be able to scale, rotate, and move/translate the created shape. The purpose is for the user to manually outline the shape of the fiducials in the received image. Infrared (e.g., SWIR) images are gray scale images (16 bit) and can be either single-focused (i.e., both the substrate and component fiducials appear in the same image) or dual-focused (only either substrate or component fiducials will appear in the image). For the image display functionality, there may be capability to scroll & zoom in and out. In some embodiments, the image dimensions may be around 600×600 pixels. The fiducial images are assumed to be captured with a suitable Z-focus. In some embodiments, there may be a functionality for manual or auto-contrast, and to adjust the brightness and contrast to highlight fiducial image features for the user to easily identify the shape outlines. Numerical values of shape dimensions are in raw units (pixel or physical) and made invariant to image zoom and scroll.

Component and substrate fiducials can be either: known common shape primitives (circle, triangle, square, rectangle, octagon, hexagon, cross) for pre-defined fiducials; or any closed polygonal shape can be represented as a set of edges/vertices. In addition, the shape can be a combinations of the shape primitives, with a known X, Y pitch.

For a given shape, the user has the flexibility to 1) import an existing shape from the existing geometric shape template files 702 for predefined fiducials, 2) overlay the imported shape on the received image, 3) resize the dimensions of the shape, 4) move the shape in the received image, 5) copy, paste and save individual shapes, and 6) give/edit to an identifiable name to the drawn shape. Shape overlay may follow a pseudo color-coding to outline the shape. The drawn dimensions of the shape (either in pixel units or physical units) may be displayed to the user. For drawing functionality, there may be an undo and redo capability.

In addition to shape dimensions, the user may also specify the relative intensity of the fiducial with respect to the image background. Relative intensity can take a binary value of {Bright, Dark} fiducial foreground with respect to the image background. Relative intensity specifies the polarity of the image edge transition.

At block 904, the method 900 may include refining the user-defined outline shape by processing the drawn shape along using the received image to precisely fit the drawn shape to the appearance of the shape in the image, to ensure that the drawn shape is geometrically consistent to the specified shape geometry (e.g., a drawn square has equal dimensions on all sides), and to correct for any labeling/drawing errors introduced by the user. In practice, once the user is done outlining the shape of the fiducial, the user may initiate processing of the user's selection by selecting a button or otherwise instructing the shape manager to refine the user-defined shape. The shape manager may perform an algorithm configured to refine and/or regularize the shape defined by the user and output an updated shape back to the user workspace (e.g., GUI).

At block 906, the refined shape may be overlaid on the displayed image (e.g., in a different color from the drawn shape) in the workspace of the user interface to illustrate to the user the refined shape. The user may further edit the refined shape and/or approve the refined shape, thereby fully specifying the refined shape parameters of the fiducial.

At block 908, the method 900 may include overlaying both the user drawn shape and the approved refined shape on the captured image to allow the user to select between which shape they would like to proceed with. At block 910, the shape parameters of the chosen shape are stored to a geometric shape template file (e.g., the JSON file) partially defining the fiducial.

FIG. 10 shows a method 1000 for completing the geometric shape template file with parameters used by the inspection module 704 for carrying out the coarse fitting and fine fitting of the method 500. At block 1002, the method 1000 may include receiving a set of multiple (e.g., one hundred) captured images of the same fiducials, either from the same location or multiple locations. In some embodiments, the shape manager 706 permits the user to move the stage 212 to a particular location (X, Y, Z, Theta) and capture one or more images either manually or by running a recipe/sequence to collect the set of images for analysis. The captured images are assumed to be well-focused and the fiducials fully appear in the images.

At block 1004, the method includes using the shape manager 706 to analyze the set of images to find an optimal set of algorithm parameters for coarse and fine fit of the fiducials in the input images. The shape manager 706 may use the shape parameters of the partially defined new geometric shape template file output by the method 900 to analyze the set of images. For each image, the shape manager may output images with the detected shapes overlaid, along with a coarse and fine fit score, and an overlay repeatability & reproducibility (ORR) metric. In some embodiments, the user may review the results of the coarse and fine fit score and the ORR metric and overlay images and confirm that the analysis is acceptable. In some embodiments, the shape manager 706 may provide a set of parameters for the user to adjust and rerun the set of captured images for image analysis. In some embodiments, the shape manager 706 may provide tools to the user for parameter tuning and dataset evaluation for a given fiducial. In some embodiments, the shape manager may include a dataset/workspace management capability and to provide the user with the ability to use multiple configurations for parameters for evaluation and comparison. In some embodiments, the shape manager may allow the user to provide static/dynamic repeatability datasets and obtain metrics therefrom (e.g., coarse and fine fit score and ORR).

At block 1006, once approved by the user, algorithm parameters used for analyzing the set of images may be saved to the new geometric shape template file output by the method 900. The new geometric shape template file may be used by the controller 106 for inspecting components and/or substrates having the fiducial shapes corresponding to the updated geometric shape template file according to the methods described herein, such as the method 500. At block 1010, the method 1000 includes creating a new fiducial inspection recipe using the saved new geometric shape template file.

The shape manager 706 also provides the ability to visualize the shape definition of the fiducial using the geometric shape template file. In some embodiments, the shape manager 706 may also include a tool for algorithm verification and debugging. In some embodiments, an inspection algorithm using a given geometric shape template file 702 may be run to ensure that the algorithm is producing results within a predetermined tolerance. In practice, a user may import an image of the component and/or substrate with fiducials along with a geometric shape template file 702 and invoke an image analysis algorithm. The image analysis algorithm may output an overlay image of the fiducials along with alignment offsets to the user for user review. The user may interactively review the output image and overlay to determine whether the results are acceptable and whether adjustments or tuning to the algorithm parameters may be desirable.

In some embodiments, the shape manager 706 may include a tool to process a batch of captured images and obtain ORR metrics from the batch processing. In practice, a user may import a set of inspection images of component and/or substrate with fiducials and may initiate an inspection algorithm to generate ORR metrics for the set of images.

The methods and systems described herein provide for estimation of misalignment between a substrate and a component with sub-pixel accuracy and precision. As a result of the improved accuracy and precision in the measurement of misalignment between component and substrate, process control of the bonding process may also be improved. A flexible user-facing system is provided that allows a user to generate geometric shape templates that may be used by the metrology system without having to adjust the algorithms used by the metrology system for estimating the misalignment between a substrate and a component.

While the foregoing is directed to embodiments of the present disclosure, other and further embodiments of the disclosure may be devised without departing from the basic scope thereof.

1. A method for processing a substrate, comprising:
for a component that is bonded to a substrate, separately detecting a substrate fiducial and a component fiducial using a captured image of the component bonded to the substrate, wherein separately detecting the substrate fiducial and the component fiducial each includes processing the captured image using a histogram of gradients and computing a two-dimensional matched filter image response to a geometric shape template to obtain a coarse fit representation of the substrate fiducial and the component fiducial at pixel-level localization accuracy, and sub-pixel fitting the two-dimensional matched filter image response to the geometric shape template to obtain a fine fit representation of the substrate fiducial and the component fiducial;
determining to sub-pixel precision, from the detected substrate fiducial and component fiducial, a center of the substrate fiducial and a center of the component fiducial;
calculating a two-dimensional positional difference between the center of the substrate fiducial and the center of the component fiducial; and
reporting the two-dimensional positional difference to a bonding system as feedback for a bonding process of a subsequent component and subsequent substrate.

2. The method of claim 1, wherein the captured image is at least one of a single-focused infrared image or a dual-focused infrared image.

3. The method of claim 1, further comprising:
modifying parameters of the bonding process based on the reported difference; and
bonding a second component to a second substrate using the bonding process.

4. The method of claim 1, further comprising generating the geometric shape template based on at least one of expected shape, size, spatial arrangement, and relative intensity polarity with respect to a background of the substrate fiducial and the component fiducial or shape of the substrate fiducial and the component fiducial.

5. The method of claim 1, wherein sub-pixel fitting includes fitting the matched filter image response to the geometric shape template around a sub-pixel spatial region of the matched filter image response.

6. The method of claim 1, wherein the geometric shape template includes one or more circular or polygonal shape.

7. The method of claim 1, further comprising:
separately detecting a second substrate fiducial and a second component fiducial using the captured image of the component bonded to the substrate;
determining, from the detected second substrate fiducial and second component fiducial, a center of the second substrate fiducial and a center of the second component fiducial;
calculating an affine transformation of the component using the center of the substrate fiducial and the center of the component fiducial, and the center of the second substrate fiducial and a center of the second component fiducial; and
reporting the affine transformation to the bonding system as feedback for the bonding process.

8. The method of claim 7, further comprising:
calculating a difference between the center of the second substrate fiducial and the center of the second component fiducial; and
reporting the difference to the bonding system as feedback for the bonding process.

9. The method of claim 7, further comprising:
modifying parameters of the bonding process based on the affine transformation; and
bonding a second component to a second substrate using the bonding process.

10. A non-transitory computer readable storage medium storing instructions, which when executed by a processor, perform a method for processing a substrate, the method comprising:
for a component that is bonded to a substrate, separately detecting a substrate fiducial and a component fiducial using a captured image of the component bonded to the substrate, wherein separately detecting the substrate fiducial and the component fiducial each includes processing the captured image using a histogram of gradients and computing a two-dimensional matched filter image response to a geometric shape template to obtain a coarse fit representation of the substrate fiducial and the component fiducial at pixel-level localization accuracy, and sub-pixel fitting the two-dimensional matched filter image response to the geometric shape template to obtain a fine fit representation of the substrate fiducial and the component fiducial;
determining to sub-pixel precision, from the detected substrate fiducial and component fiducial, a center of the substrate fiducial and a center of the component fiducial;
calculating a two-dimensional positional difference between the center of the substrate fiducial and the center of the component fiducial; and
reporting the two-dimensional positional difference to a bonding system as feedback for a bonding process of a subsequent component and subsequent substrate.

11. The non-transitory computer readable storage medium of claim 10, wherein the captured image is at least one of a single-focused infrared image or a dual-focused infrared image.

12. The non-transitory computer readable storage medium of claim 10, wherein the method further comprises:
modifying parameters of the bonding process based on the reported difference; and
bonding a second component to a second substrate using the bonding process.

13. The non-transitory computer readable storage medium of claim 10, wherein the method further comprises generating the geometric shape template based on at least one of expected shape, size, spatial arrangement, and relative intensity polarity with respect to a background of the substrate fiducial and the component fiducial or shape of the substrate fiducial and the component fiducial.

14. The non-transitory computer readable storage medium of claim 10, wherein sub-pixel fitting includes fitting the matched filter image response to the geometric shape template around a sub-pixel spatial region of the matched filter image response.

15. The non-transitory computer readable storage medium of claim 10, wherein the geometric shape template includes one or more circular or polygonal shape.

16. The non-transitory computer readable storage medium of claim 10, wherein the method further comprises:
separately detecting a second substrate fiducial and a second component fiducial using the captured image of the component bonded to the substrate;
determining, from the detected second substrate fiducial and second component fiducial, a center of the second substrate fiducial and a center of the second component fiducial;
calculating an affine transformation of the component using the center of the substrate fiducial and the center of the component fiducial, and the center of the second substrate fiducial and a center of the second component fiducial; and
reporting the affine transformation to the bonding system as feedback for the bonding process.

17. The non-transitory computer readable storage medium of claim 16, wherein the method further comprises:
calculating a difference between the center of the second substrate fiducial and the center of the second component fiducial; and
reporting the difference to the bonding system as feedback for the bonding process.

18. The non-transitory computer readable storage medium of claim 16, wherein the method further comprises:
modifying parameters of the bonding process based on the affine transformation; and
bonding a second component to a second substrate using the bonding process.

19. A system comprising:
an image acquisition device configured to capture an infrared image of a component fiducial on a component and substrate fiducial on a substrate that is bonded to the component; and
a controller configured to:
separately detect the substrate fiducial and the component fiducial using the captured infrared image, wherein separately detecting the substrate fiducial and the component fiducial each includes processing the infrared image using a histogram of gradients and computing a two-dimensional matched filter image response to a geometric shape template to obtain a coarse fit representation of the substrate fiducial and the component fiducial at pixel-level localization accuracy, and sub-pixel fitting the two-dimensional matched filter image response to the geometric shape template to obtain a fine fit representation of the substrate fiducial and the component fiducial;
determine to sub-pixel precision, from the detected substrate fiducial and component fiducial, a center of the substrate fiducial and a center of the component fiducial;
calculate a two-dimensional positional difference between the center of the substrate fiducial and the center of the component fiducial; and
report the two-dimensional positional difference to a bonding system as feedback for a bonding process of a subsequent component and subsequent substrate.

20. The system of claim 19, wherein sub-pixel fitting includes fitting the matched filter image response to the geometric shape template around a sub-pixel spatial region of the matched filter image response.
